(19) United States
(12) Patent Application Publication
(10) Pub. No.: US 2007/0173043 A1
(43) Pub. Date: Jul. 26, 2007

(54) Ion implantation system having variable screen aperture and ion implantation method using the same

(76) Inventors: Seung-hee Lee, Hwaseong-si (KR); Young-soo Yang, Suwon-si (KR); Seung-chul Kim, Suwon-si (KR); Chan-seung Choi, Suwon-si (KR); Won-bae Jang, Osan-si (KR); Min-suk Kim, Suwon-si (KR)

Correspondence Address: LEE & MORSE, P.C., 3141 FAIRVIEW PARK DRIVE, SUITE 500, FALLS CHURCH, VA, 22042, US

(21) Appl. No.: 11/655,114

(22) Filed: Jan. 19, 2007

(30) Foreign Application Priority Data
Jan. 26, 2006 (KR) 10-2006-0008289

(51) Int. Cl. H01L 21/425

(52) U.S. Cl. 438/514; 257/E21.147

(57) ABSTRACT

An ion implantation system includes a source portion, a beam line portion, a target chamber having a platen, and a Faraday portion having a dose cup and a first variable screen aperture, wherein the platen is capable of moving in a second direction and supporting a semiconductor substrate, and the first variable screen aperture includes a first opening having a first adjustable width along a first direction.

### BACKGROUND OF THE INVENTION

1. Field of the Invention

The present invention relates to ion implantation systems employed in fabrication of semiconductor devices. In particular, the present invention relates to an ion implantation system capable of implanting impurities having different properties into various predetermined regions of a single semiconductor substrate and to a method using the same.

2. Description of the Related Art

In general, an ion implantation system refers to an apparatus capable of converting an N-type impurity or a P-type impurity into ions and depositing them into a semiconductor substrate by way of an ion beam to form, for example, a well, a channel, or source and drain regions in the semiconductor substrate, thereby improving the conductivity and resistance thereof.

In a conventional ion implantation process the properties of the impurity ions, e.g., types of impurity ions, impurity ion concentrations, ion implantation energies, and so forth, may be modified to provide an optimal semiconductor device operation. Testing of such devices may be done by implanting ions having one specific property into a respective semiconductor substrate prior to analyzing the operation of the semiconductor device. However, since only one property may be tested at a time, the conventional ion implantation process may require multiple semiconductor substrates for proper testing, thereby increasing manufacturing time and costs. Further, since the semiconductor device may require complete assembly to perform proper testing, various factors other than properties of the impurity ions may influence the test results, thereby reducing accuracy thereof.

In another conventional method, photoresist patterns and stencil masks may be used to facilitate implantation of ions corresponding to a plurality of properties into a single semiconductor substrate. More specifically, a plurality of photoresist patterns or stencil masks may be formed on a semiconductor substrate, such that ions having different properties may be implanted into various regions of the semiconductor substrate using the respective photoresist patterns or stencil masks as ion implantation masks. However, such methods may be very expensive and result in lower productivity. Further, use of a stencil mask having a predetermined pattern may require frequent changing with respect to the semiconductor device and the location and pattern of the predetermined substrate region.

Accordingly, there exists a need for an efficient ion implantation system capable of providing selective implantation of ions having different properties into various predetermined regions of a single semiconductor substrate.

### SUMMARY OF THE INVENTION

The present invention is therefore directed to an ion implantation system and a method employing the same, which substantially overcome one or more of the problems due to the limitations and disadvantages of the related art.

It is therefore a feature of an embodiment of the present invention to provide an ion implantation system having a structure capable of selectively implanting ions having different properties into various predetermined regions of a single semiconductor substrate.

It is another feature of an embodiment of the present invention to provide a method of implanting ions having different properties into predetermined regions of a single semiconductor substrate, while providing accurate test results and maintaining efficient manufacturing costs.

At least one of the above and other features and advantages of the present invention may be realized by providing an ion implantation system, including a source portion, a beam line portion, a target chamber having a platen, the platen capable of moving in a first direction and supporting a semiconductor substrate, and a Faraday portion having a dose cup and a first variable screen aperture, wherein the first variable screen aperture may include a first opening having a first adjustable width along a first direction. The first direction may be perpendicular to the second direction. Additionally, the beam line portion may include an accelerator, a scanner, and a focusing unit.

The first variable screen aperture may include first and second screen members having the first opening therebetween, each of the first and second screen members may be independently movable along the first direction. Further, the first variable screen aperture may include graphite.

The Faraday portion may be disposed inside the target chamber. Additionally, the Faraday portion may further include a second variable screen aperture having a second opening with a second adjustable width along the second direction. The second variable screen aperture may include third and fourth screen members having the second opening therebetween, each of the third and fourth screen members may be independently movable along the second direction.

In another aspect of the present invention, there is provided an ion implantation method, including generating an ion beam, accelerating the ion beam toward a scanner, scanning the accelerated ion beam in a first direction, adjusting the scanned ion beam in the first direction by varying a first variable screen aperture in the first direction, implanting the adjusted ion beam into a semiconductor substrate attached to a platen, and moving the platen in a second direction. The first direction may be perpendicular to the second direction.

Adjusting the scanned ion beam in the second direction may include setting a width and a position thereof with respect to the semiconductor substrate. Setting a width and a position of the ion beam may include independently moving first and second screen members of the first variable screen aperture along the first direction. Additionally, setting the width and the position of the ion beam may further include positioning the first and second screen members to correspond to a half of the semiconductor substrate. Alternatively, setting the width and the position of the ion beam may further include positioning the first and second screen members to correspond to a column die of the semiconductor substrate. Setting the width and the position of the ion beam may also include positioning the first and second screen members at a first speed and moving the platen at a second speed.

The ion implantation method may also include adjusting the scanned ion beam in the second direction by varying a second variable screen aperture in the second direction. Adjusting the scanned ion beam in the second direction may include setting a height and a position thereof with respect to the semiconductor substrate. Setting a height and a position of the ion beam may include independently moving third and fourth screen members of the second variable screen aperture along the second direction.

### BRIEF DESCRIPTION OF THE DRAWINGS

The above and other features and advantages of the present invention will become more apparent to those of ordinary skill in the art by describing in detail exemplary embodiments thereof with reference to the attached drawings, in which:

FIG. 1 illustrates a schematic diagram of an ion implantation system according to an exemplary embodiment of the present invention;

FIG. 2 illustrates a top plan view of a target chamber of the ion implantation system illustrated in FIG. 1;

FIG. 3 illustrates a cross-sectional view of the target chamber illustrated in FIG. 2;

FIG. 4 illustrates a front elevation view of the target chamber illustrated in FIG. 2;

FIG. 5 illustrates a top plan view of a target chamber of an ion implantation according to another embodiment of the present invention;

FIG. 6 illustrates a cross-sectional view of the target chamber illustrated in FIG. 5;

FIG. 7 illustrates a front elevation view of the target chamber illustrated in FIG. 5;

FIG. 8 illustrates a top plan view of the target chamber of the ion implantation system illustrated in FIG. 1 during an ion implantation process according to an embodiment of the present invention;

FIGS. 9-10 illustrate top plan views of semiconductor substrates treated according to the method illustrated in FIG. 8;

FIG. 11 illustrates a top plan view of the target chamber of the ion implantation system illustrated in FIG. 1 during an ion implantation process according to another embodiment of the present invention;

FIG. 12 illustrates a top plan view of a semiconductor substrate treated according to the method illustrated in FIG. 11; and

FIGS. 13 and 14 illustrate top plan views of semiconductor substrates treated by the ion implantation system illustrated in FIG. 5.

### DETAILED DESCRIPTION OF THE INVENTION

Korean Patent Application No. 10-2006-0008289, filed on Jan. 26, 2006, in the Korean Intellectual Property Office, and entitled: “Ion Implantation System Having Variable Screen Aperture and Ion Implantation Method Using the Same,” is incorporated by reference herein in its entirety.

The present invention will now be described more fully hereinafter with reference to the accompanying drawings, in which exemplary embodiments of the invention are illustrated. The invention may, however, be embodied in different forms and should not be construed as limited to the embodiments set forth herein. Rather, these embodiments are provided so that this disclosure will be thorough and complete, and will fully convey the scope of the invention to those skilled in the art.

It will further be understood that when an element is referred to as being “on” another element or substrate, it can be directly on the other element or substrate, or intervening elements may also be present. Further, it will be understood that when an element is referred to as being “under” another element, it can be directly under, or one or more intervening elements may also be present. In addition, it will also be understood that when an element is referred to as being “between” two elements, it can be the only element between the two elements, or one or more intervening elements may also be present. In contrast, when an element is referred to as being “directly on,” there may be no intervening elements or layers present. Like reference numerals refer to like elements throughout.

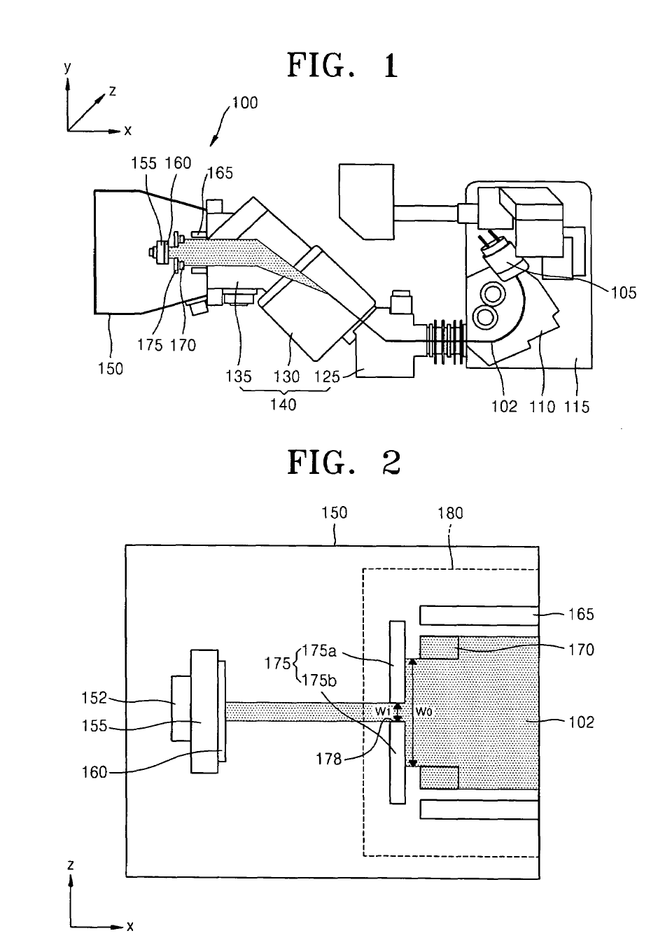

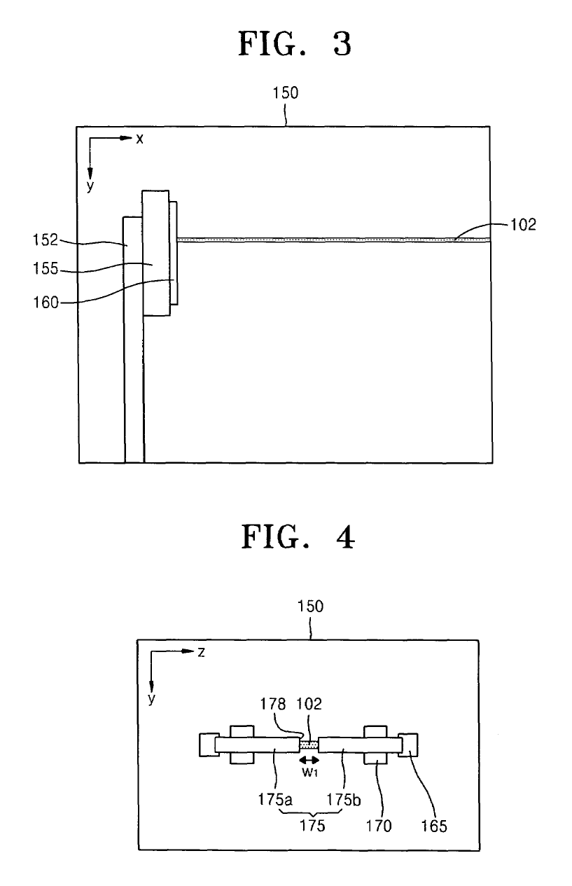

An exemplary embodiment of an ion implantation system according to the present invention will now be more fully described with respect to FIGS. 1-4. As illustrated in FIGS. 1-4, an ion implantation system 100 may include a source portion 115, a beam line portion 140 and a target chamber 150. Accordingly, an ion beam 102 may be generated by the source portion 115, advanced into the beam line portion 140, and implanted into a semiconductor substrate 160 in the target chamber 150.

The source portion 115 of the ion implantation system 100 may have a typical structure in the art. For example, the source portion 115 may include an ion source 105 and a mass analyzer 110. The ion source 105 may convert impurities into ions and advance the impurity ions into the mass analyzer 110. The mass analyzer 110 may include a magnet (not shown) capable of selecting impurity ions according to the mass thereof and generating the ion beam 102. The ion beam 102 may be advanced into the beam line portion 140. Accordingly, the source portion 115 may be in communication with the beam line portion 140 to facilitate passage of the ion beam 102 therethrough.

The beam line portion 140 of the ion implantation system 100 may accelerate the ion beam 102 to a predetermined energy level and provide thereto a specific angle and direction. In particular, the beam line portion 140 may include an accelerator 125, a scanner 130 and a focusing unit 135. The accelerator 125 may receive the ion beam 102 from the source portion 115 and impart a predetermined amount of energy thereto, such that the ion beam 102 may be accelerated into the scanner 130.

The scanner 130 may scan the accelerated ion beam 102 in one predetermined direction. For example, if the ion beam 102 is accelerated into the scanner 130 as a one-dimensional linear beam, the scanner 130 may convert the linear beam into a two-dimensional planar beam directed in the same direction as the one-dimensional linear beam and having a predetermined width. The scanned ion beam 102 may be advanced into the focusing unit 135, such that a direction of the scanned ion beam 102 may be changed and focused in a predetermined direction with respect to the target chamber 150. Once the direction of the scanned ion beam 102 is set, the set ion beam 102 may be advanced into the target chamber 150. Accordingly, the beam line portion 140 may be in communication with the target chamber 150 to facilitate passage of the ion beam 102 therethrough. The structures of the scanner 130 and the focusing unit 135 may be well known in the art, and thus, their detailed descriptions will not be provided herein.

The target chamber 150 of the ion implantation system 100 according to an embodiment of the present invention may include a Faraday portion 180, a platen 155 for supporting the semiconductor substrate 160, and a supporting member 152. The scanned ion beam 102 may be advanced from the beam line portion 140 into the target chamber 150 through the Faraday portion 180, such that a width and a position thereof may be adjusted in the Faraday portion 180 before being implanted into the semiconductor substrate 160. In this respect, it should be noted that a width of the ion beam 102 as adjusted in the Faraday portion 180 refers to a distance measured along a first direction, e.g., along a z-axis, as illustrated in FIGS. 2 and 4. Similarly, a position of the ion beam 102 as adjusted in the Faraday portion 180 refers to a location along the first direction with respect to the semiconductor substrate 160.

The Faraday portion 180, as illustrated in FIG. 2, may be positioned inside the target chamber 150 between the beam line portion 140 and the substrate 160. However, other embodiments, e.g., positioning of the Faraday portion 180 outside the target chamber 150 between the target chamber 150 and the beam line portion 140, are not excluded from the scope of the present invention. The Faraday portion 180 may include a dose cup 170, a stationary screen aperture 165, and a first variable screen aperture 175.

The dose cup 170 of the Faraday portion 180 may be used to measure the quantity of ions injected by the ion beam 102 by any method known in the art, e.g., by measuring a flux of the ion beam 102. The stationary screen aperture 165 of the Faraday portion 180 may have a predetermined width to facilitate advancement of the ion beam 102 through the dose cup 170 upon acceleration from the beam line portion 140 toward the substrate 160 and to prevent the ion beam 102 from being incident on walls of the target chamber 150. The first variable screen aperture 175 of the Faraday portion 180 may be formed of graphite and, as opposed to the stationary screen aperture 165, be movable along the first direction.

In particular, the variable screen aperture 175 may include a first opening 178 having a first adjustable width. More specifically, the variable screen aperture 175 may include a first screen member 175a and a second screen member 175b defining the first opening 178, such that each of the first and second screen members 175a and 175b may move independently along the first direction to modify a width and a location of the first opening 178 along the first direction. For example, the first and second screen members 175a and 175b may be moved along the z-axis, as illustrated in FIG. 2, to position the first opening 178 across from a center of the semiconductor substrate 160 with a first adjustable width of W₁. Accordingly, a width of the ion beam 102 passing through the first variable screen aperture 175 may be decreased from Wₒ, i.e., a width of the ion beam 102 passing through the dose cup 170 as measured along the z-axis, to W₁, i.e., a width set by the adjustable width of the first opening 178. As a result, ions may be implanted into a center region of the semiconductor substrate 160 having a width W₁.

It should be noted that since the functions of the stationary screen aperture 165 and the first variable screen aperture 175 may be similar, the stationary screen aperture 165 may be omitted.

The platen 155 of the target chamber 150 according to an embodiment of the present invention may include a clamp to support the semiconductor substrate 160. Further, the platen 155 may be capable of moving along a supporting member 152 in parallel to a second direction, e.g., along a y-axis, to provide a hybrid scan. In other words, the ion beam 102 may be scanned and focused in the beam line portion 140 in the first direction, e.g., along the z-axis, by an electromagnetic method, while the platen 155 holding the semiconductor substrate 160 in the target chamber 150 may move in the second direction, e.g., along the y-axis, by a mechanical method. In this respect, it should be noted that the first and second directions may be perpendicular. Accordingly, the ion beam 102 may be implanted into a predetermined region of the semiconductor substrate 160 or over the entire region of the semiconductor substrate 160 by employing a hybrid scan of electromagnetic and mechanical methods in perpendicular directions.

The semiconductor substrate 160 employed in the present invention may be any suitable substrate employed in the art for fabrication of semiconductor devices. In particular, the semiconductor substrate 160 may be divided into columns of die units (not shown) in order to fabricate a plurality of semiconductor chips. For example, a plurality of die units may be arranged on the semiconductor substrate 160 in a two dimensional matrix. The semiconductor substrate 160 may be a silicon substrate, a germanium substrate or a silicon-germanium substrate.

Without intending to be bound by theory, it is believed that the ion implantation apparatus 100 according to an embodiment of the present invention may be more advantageous as compared to conventional ion implantation apparatuses because impurity ions having different properties may be selectively implanted into various predetermined regions of a single semiconductor substrate 160 by adjusting the location and width of the first opening 178 of the first variable screen aperture 175. Use of the first variable screen aperture 175 may eliminate the use of photoresist patterns or stencil masks and minimize the required number of semiconductor substrates, thereby providing a process having improved accuracy and reliability and overall efficient throughput and reduced costs.

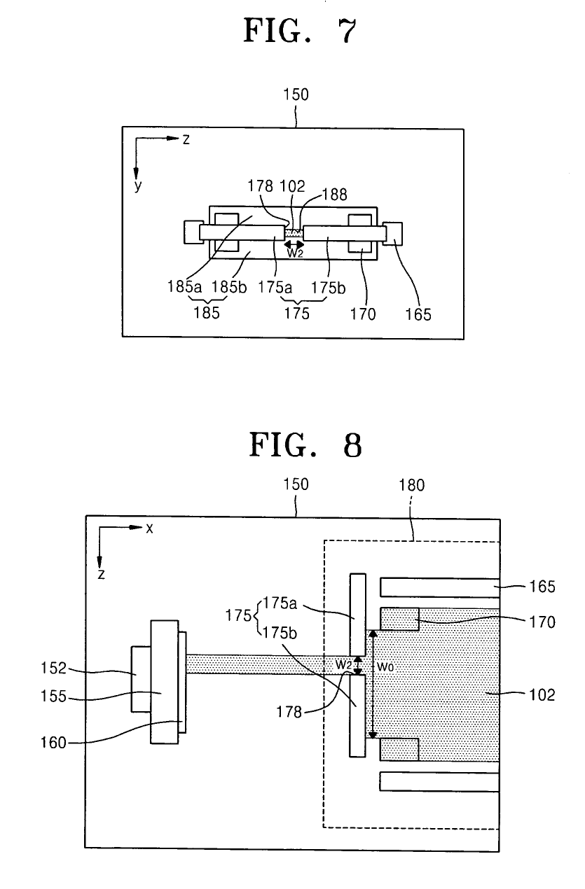

In another embodiment illustrated in FIGS. 5-7, an ion implantation system according to the present invention may be similar to the ion implantation system 100 illustrated in FIGS. 1-4 with the exception that it may include a Faraday portion 180a having a second variable screen aperture 185 in addition to the components included in the Faraday portion 180 illustrated in FIG. 2.

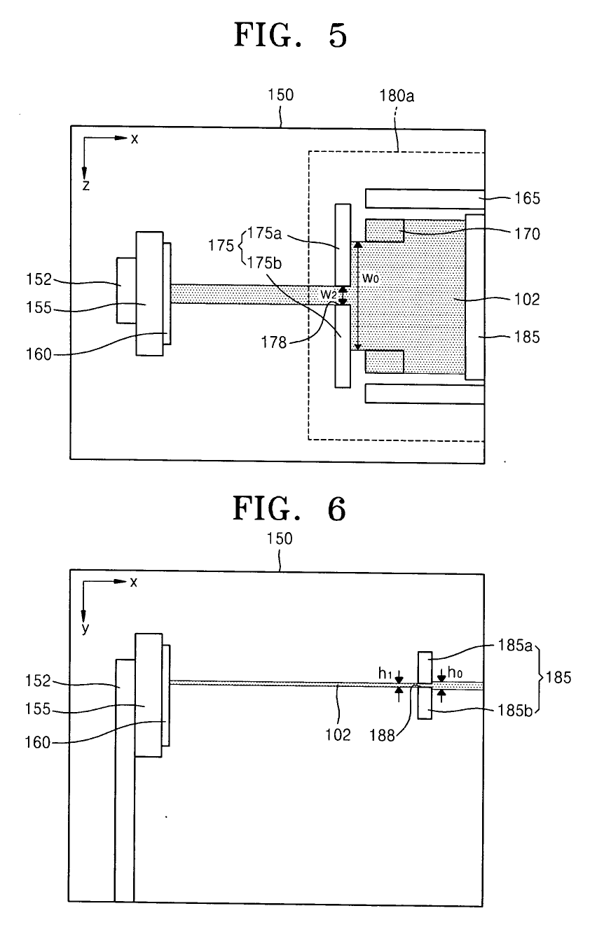

The second variable screen aperture 185 of the Faraday portion 180a may be formed of graphite and be movable along the second direction. In particular, the second variable screen aperture 185 may include a second opening 188 having a second adjustable width. More specifically, the second variable screen aperture 185 may include a third screen member 185a and a fourth screen member 185b defining the second opening 188, as illustrated in FIG. 6, such that each of the third and fourth screen members 185a and 185b may move independently along the second direction to modify a width and a location of the second opening 188 along the second direction. For example, the third and fourth screen members 185a and 185b may be moved along the y-axis, as illustrated in FIG. 6, to position the second opening 188 across from the semiconductor substrate 160 with a second adjustable width of h₁. In this respect, it should be noted that the second adjustable width of the second opening 188 refers to a height of the ion beam 102 as measured along the y-axis. Accordingly, the height of the ion beam 102 may be adjusted from h₀ to h₁, as illustrated in FIG. 6.

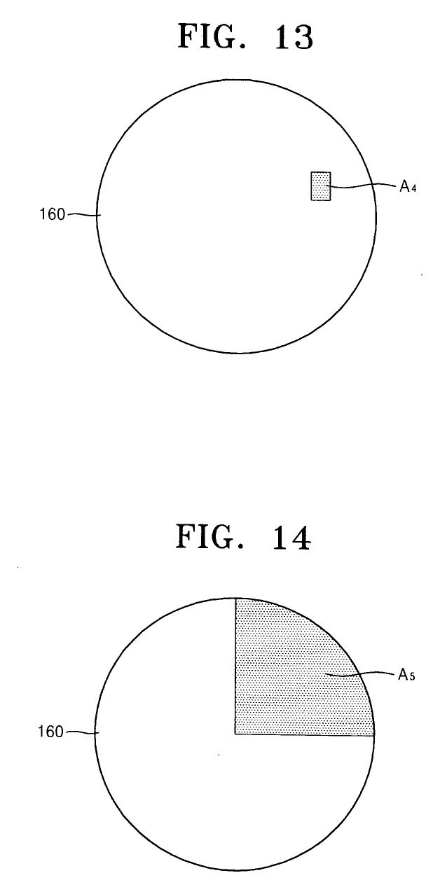

Additionally, the second variable screen aperture 185 may block the ion beam 102 by completely closing the second opening 188 with respect to a predetermined region of the semiconductor substrate 160. Blocking of the ion beam 102 may be beneficial when only a specific column of dies of the semiconductor substrate 160 is treated with impurity ions, as will be discussed in more detail below with respect to FIGS. 13-14.

In another embodiment of the present invention a method of implanting ions into a semiconductor substrate by the ion implantation systems, previously described with respect to FIGS. 1-7, will be described in detail below. It should be noted, however, that even though the methods of implanting ions into a semiconductor substrate will be described with respect to the ion implantation systems illustrated in FIGS. 1-7, other ion implantation systems are not excluded from the scope of the present invention.

As described previously with respect to FIGS. 14, the ion beam 102 may be generated by the source portion 115 and accelerated by the accelerator 125 toward the scanner 130. Next, the ion beam 102 may be scanned and focused in one direction in the line beam portion 140, and adjusted by the first variable screen aperture 175 toward a predetermined region of the semiconductor substrate 160. While the ion beam 102 may be electromagnetically adjusted along the z-axis, the platen 155 supporting the semiconductor substrate 160 may be mechanically moved along the y-axis to provide hybrid ion implantation in two directions.

A method of scanning and adjusting the ion beam 102 toward a predetermined region of the semiconductor substrate 160 will be further described with respect to FIGS. 8-10.

First, the first opening 178 of the first variable screen aperture 175 may be adjusted to correspond to a specific region of the semiconductor substrate 160, as illustrated in FIG. 8. For example, the first and second screen members 175a and 175b may be positioned such that the first opening 178 may have a width of W₂ across from a specific column of dies of the semiconductor substrate 160.

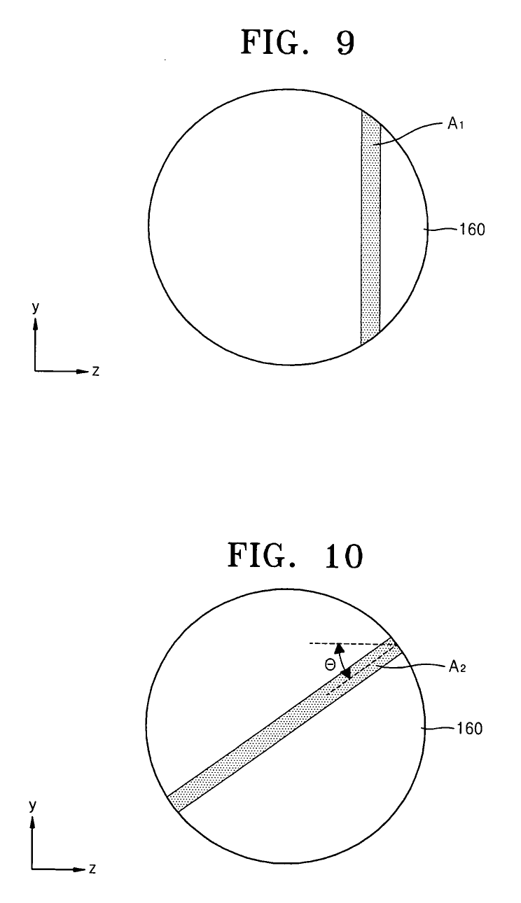

Next, the semiconductor substrate 160 may be moved vertically, i.e., along the y-axis, by the platen 155, such that the impurity ions from the ion beam 102 may be implanted along the specific column of dies Al of the semiconductor substrate 160, as illustrated in FIG. 9. The ion implantation procedure described with respect to FIGS. 8-9 may be repeated, while the first opening 178 may be adjusted in terms of width and positioning along the z-axis to provide ion implantation to additional columns of dies positioned in parallel to region A₁. In this respect, it should be noted that every time the ion implantation procedure described with respect to FIGS. 8-9 is repeated on the same semiconductor substrate 160, the ion implantation properties, e.g., amount of energy, amount of impurity ions, and so forth, for each column of dies may be modified.

Alternatively, the semiconductor substrate 160 may be positioned on the platen 155, such that a column of dies A₂ to be treated with the ion implantation beam 102 may be tilted at a predetermined angle with respect to the z-axis, as illustrated in FIG. 10. In other words, when the semiconductor substrate 160 is tilted upon loading onto the platen 155, such that the columns of dies are tilted as well, the ion implantation may be adjusted to correspond to the tilt.

For example, the position of the first opening 178 of the first variable screen aperture 175 may be maintained at a constant width and moved along the z-axis, while the platen 155 may be moved along the y-axis. A tilt angle, a displacement speed of the first opening 178, and a moving speed of the platen 155 may satisfy Equation 1, where θ is the tilt angle with respect to the z-axis, Vₚ is the moving speed of the platen 155, i.e., a second speed, and Vₒ is the displacement speed of the first opening 178, i.e., movement of the first and second screen members 175a and 175b at a first speed.

Vₒ=Vₚ/tan(θ) (Equation 1)

Accordingly, as can be seen in Equation 1, adjustment of speeds of the first opening 178 and the platen 155 may facilitate ions implantation in regions tilted at predetermined angles θ with respect to the z-axis.

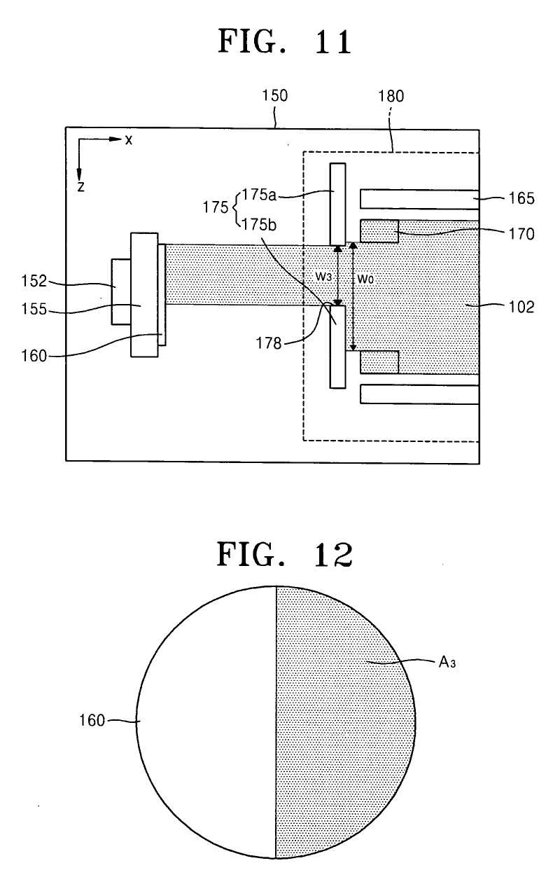

Another method for implanting impurity ions into the semiconductor substrate 160 may include selective ion implantation into large regions thereof. For example, impurity ions may be implanted in a half region A₃ of the semiconductor substrate 160, as illustrated in FIG. 12. In particular, as illustrated in FIG. 11, the first opening 178 of the first variable screen aperture 175 may be adjusted to have an adjustable width W₃, i.e., a width corresponding to the half region A₃ of the semiconductor substrate 160, and positioned across from the half region A₃ of the semiconductor substrate 160 to be implanted, i.e., one end of the second screen member 175b may be disposed in front of the center of the semiconductor substrate 160, and one end of the first screen member 175a may be disposed in front of an edge of the semiconductor substrate 160. It should be noted that reversing the positions of the first and second screen members 175a and 175b may provide an appropriate set up of the first opening 178 for ion implantation in a half region opposite the half region A₃.

Yet another method for implanting impurity ions into the semiconductor substrate 160 may include selective ion implantation into regions thereof by adjusting the second variable screen aperture 185. For example, the second opening 188 of the second variable screen aperture 185 may be closed completely to facilitate control of ion implantation onto specific columns of dies of the semiconductor substrate 160, e.g., regions A₄ and A₅, as illustrated in FIGS. 13-14. More specifically, the ion implantation illustrated in FIG. 13 may be accomplished by employing the ion implantation method described with respect to FIG. 9 with the exception that opening of the second opening 188 of the second variable screen aperture 185 may occur only when the platen 155 passes the region A₄. Alternatively, the ion implantation illustrated in FIG. 14 may be accomplished by employing the ion implantation method described with respect to FIG. 11 with the exception that opening of the second opening 188 of the second variable screen aperture 185 may occur only when the platen 155 passes the region A₅.

Exemplary embodiments of the present invention have been disclosed herein, and although specific terms are employed, they are used and are to be interpreted in a generic and descriptive sense only and not for purpose of limitation. For example, an ion implantation system according to exemplary embodiments of the present invention should not be restricted to the kinds of impurity ions implanted, e.g., ions of phosphorus, boron, germanium, silicon, indium, antimony, nitrogen, and argon. Accordingly, it will be understood by those of ordinary skill in the art that various changes in form and details may be made without departing from the spirit and scope of the present invention as set forth in the following claims.

What is claimed is:

1. An ion implantation system, comprising:
a source portion;
a beam line portion;
a target chamber having a platen, the platen capable of moving in a second direction and of supporting a semiconductor substrate; and
a Faraday portion having a dose cup and a first variable screen aperture, wherein the first variable screen aperture includes a first opening having a first adjustable width along a first direction.

2. The ion implantation system as claimed in claim 1, wherein the first variable screen aperture includes first and second screen members having the first opening therebetween, each of the first and second screen members is independently movable along the first direction.

3. The ion implantation system as claimed in claim 2, wherein the first variable screen aperture includes graphite.

4. The ion implantation system as claimed in claim 1, wherein the Faraday portion is disposed inside the target chamber.

5. The ion implantation system as claimed in claim 1, wherein the beam line portion includes an accelerator, a scanner, and a focusing unit.

6. The ion implantation system as claimed in claim 1, wherein the Faraday portion further comprises a second variable screen aperture having a second opening with a second adjustable width along the second direction.

7. The ion implantation system as claimed in claim 1, wherein the first direction is perpendicular to the second direction.

8. The ion implantation system as claimed in claim 7, wherein the second variable screen aperture includes third and fourth screen members having the second opening therebetween, each of the third and fourth screen members being independently movable along the second direction.

9. An ion implantation method, comprising:
generating an ion beam;
accelerating the ion beam toward a scanner;
scanning the accelerated ion beam in a first direction;
adjusting the scanned ion beam in the first direction by varying a first variable screen aperture in the first direction;
implanting the adjusted ion beam into a semiconductor substrate attached to a platen; and
moving the platen in a second direction.

10. The ion implantation method as claimed in claim 9, wherein adjusting the scanned ion beam in the first direction includes setting a width and a position thereof with respect to the semiconductor substrate.

11. The ion implantation method as claimed in claim 10, wherein setting a width and a position of the ion beam includes independently moving first and second screen members of the first variable screen aperture along the first direction.

12. The ion implantation method as claimed in claim 11, wherein setting the width and the position of the ion beam further comprises positioning the first and second screen members to correspond to a half of the semiconductor substrate.

13. The ion implantation method as claimed in claim 11, wherein setting the width and the position of the ion beam further comprises positioning the first and second screen members to correspond to a column die of the semiconductor substrate.

14. The ion implantation method as claimed in claim 11, wherein setting the width and the position of the ion beam further comprises positioning the first and second screen members at a first speed and moving the platen at a second speed.

15. The ion implantation method as claimed in claim 9, further comprising adjusting the scanned ion beam in the second direction by varying a second variable screen aperture in the second direction.

16. The ion implantation method as claimed in claim 15, wherein adjusting the scanned ion beam in the second direction includes setting a height and a position thereof with respect to the semiconductor substrate.

17. The ion implantation method as claimed in claim 16, wherein setting a height and a position of the ion beam includes independently moving third and fourth screen members of the second variable screen aperture along the second direction.

18. The ion implantation method as claimed in claim 9, wherein the first direction is perpendicular to the second direction.
